(19) United States
(12) Patent Application Publication
(10) Pub. No.: US 2022/0310557 A1
(43) Pub. Date: Sep. 29, 2022

(54) WAFER LAMINATING METHOD

(71) Applicant: DISCO CORPORATION, Tokyo (JP)

(72) Inventor: Masaru NAKAMURA, Tokyo (JP)

(21) Appl. No.: 17/656,090

(22) Filed: Mar. 23, 2022

(30) Foreign Application Priority Data
Mar. 26, 2021 (JP) 2021-052658

(51) Int. Cl. H01L 23/00

(52) U.S. Cl. CPC H01L 24/83; H01L 24/27; H01L 24/29; H01L 2224/2741; H01L 2224/83054; H01L 2224/832; H01L 2224/29194

(57) ABSTRACT

A wafer laminating method includes a cooling step of cooling a first wafer, a laminating step of producing a laminated wafer by stacking and laminating a second wafer on a surface of the first wafer when condensation forms on the surface of the cooled first wafer, and a heat treatment step of subjecting the laminated wafer to heat treatment.

### BACKGROUND OF THE INVENTION

### Field of the Invention

The present invention relates to a wafer laminating method of laminating a first wafer and a second wafer to each other.

### Description of the Related Art

A document titled “Wafer Direct Bonding” (Takagi Hideki. Wafer Direct Bonding. Website of National Institute of Advanced Industrial Science and Technology. https://staff.aist.go.jp/takagi.hideki/waferbonding.html (accessed 2021-2-17)) discloses a technology of directly laminating two wafers. This technology is used to fabricate a silicon-on-insulator (SOI) wafer.

This technology includes preprocessing that forms an oxide film by slightly oxidizing surfaces of the wafers with use of such a chemical as an acid and pure water, and makes a large number of hydroxyls adhere to the surfaces, and postprocessing that superposes the wafers on each other and bonds the wafers to each other, and makes coupling between the wafers firm by heat treatment of the wafers at a high temperature of 1000° C. or higher.

### SUMMARY OF THE INVENTION

However, the above-described technology uses an attractive force between the surfaces of the wafers when the wafers are superposed on each other and bonded to each other. Thus, the surfaces of the respective wafers need to be brought close to each other to such a degree that a sufficient attractive force between the surfaces acts on atoms of the surfaces of the respective wafers. The surfaces of the respective wafers hence need to be smoothed at a level of one nanometer or less in preprocessing. Accordingly, there is room for improvement in terms of productivity.

It is accordingly an object of the present invention to provide a wafer laminating method that can produce a laminated wafer easily.

In accordance with an aspect of the present invention, there is provided a wafer laminating method of laminating a first wafer and a second wafer to each other, the wafer laminating method including a cooling step of cooling the first wafer, a laminating step of producing a laminated wafer by stacking and laminating the second wafer on a surface of the first wafer when condensation forms on the surface of the cooled first wafer, and a heat treatment step of subjecting the laminated wafer to heat treatment.

Preferably, the first wafer and the second wafer are each a silicon wafer. Preferably, in the heat treatment step, the laminated wafer is subjected to the heat treatment at a temperature of 1000° C. to 1100° C.

According to the wafer laminating method in accordance with the present invention, it is possible to produce a laminated wafer easily, and hence improve productivity.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view of a first wafer and a cooling table;

FIG. 1B is a perspective view illustrating a state in which a cooling step is being performed;

FIG. 2 is a perspective view illustrating a state in which a laminating step is being performed;

FIG. 3 is a perspective view of a laminated wafer; and

FIG. 4 is a perspective view illustrating a state in which a heat treatment step is being performed.

### DETAILED DESCRIPTION OF THE PREFERRED EMBODIMENT

A preferred embodiment of a wafer laminating method of laminating a first wafer and a second wafer to each other will hereinafter be described with reference to the drawings.

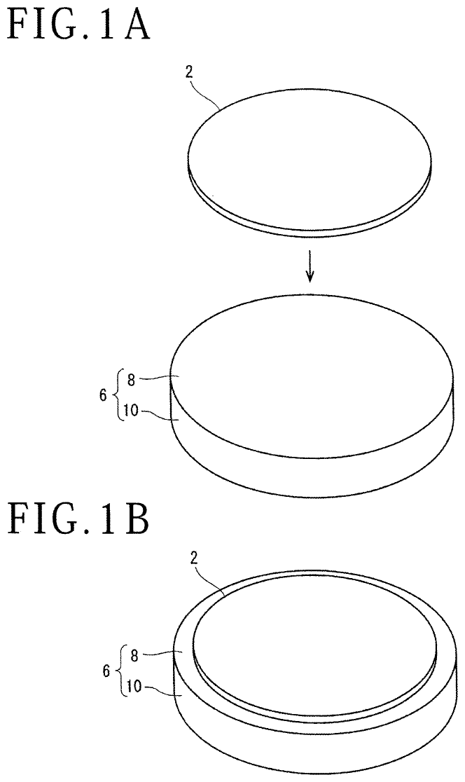

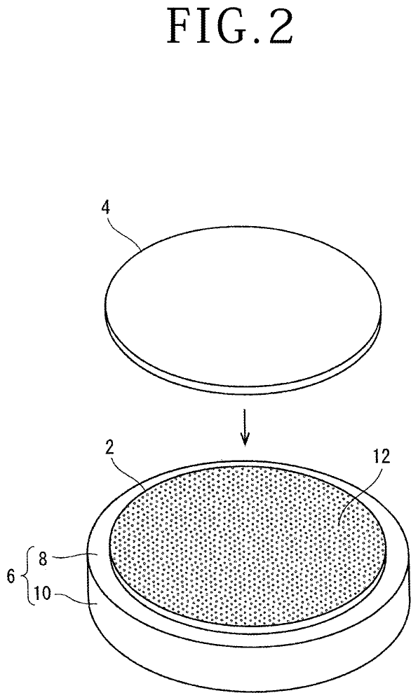

Described with reference to FIG. 1A and FIG. 1B, the present embodiment first performs a cooling step of cooling a first wafer 2. The first wafer 2 may be a disk-shaped silicon wafer. In addition, as with the first wafer 2, a second wafer 4 (see FIG. 2) may be a disk-shaped silicon wafer. Incidentally, a top surface and an undersurface of each of the first and second wafers 2 and 4 do not have such devices as integrated circuits (ICs) or large-scale integration circuits (LSIs) formed thereon, and the first and second wafers 2 and 4 are simply sliced from a cylindrical silicon ingot. However, the first and second wafers 2 and 4 may be a wafer having devices formed on the top surface thereof. In addition, while the lamination surface of each of the first and second wafers 2 and 4 needs to be smoothed by grinding or polishing, high-precision smoothing at a level of one nanometer or less is not required.

The cooling step can be performed by using a cooling table 6 illustrated in FIG. 1A, for example. The cooling table 6 includes a top 8 in a circular shape and a side wall 10 hanging down from the peripheral edge of the top 8. The diameter of the top 8 is larger than the diameter of the first and second wafers 2 and 4, so that the first and second wafers 2 and 4 can be mounted on the top 8 of the cooling table 6. The cooling table 6 is configured to cool an object to be cooled which is placed on the top 8.

Continuously described with reference to FIG. 1A and FIG. 1B, in the cooling step according to the present embodiment, the first wafer 2 is mounted on the upper surface of the cooling table 6, and the first wafer 2 is cooled. When the first wafer 2 is cooled, the cooling table 6 on which the first wafer 2 is mounted is preferably placed under an atmosphere of relatively high humidity at a temperature higher than that of the upper surface of the top 8 (for example, a humidity of approximately 40% to 60% at room temperature).

However, the cooling step is not limited to such a mode. The first wafer 2 may be put inside a freezer (for example, at an internal temperature of approximately −20° C. to 0° C.), and the whole of the first wafer 2 may be cooled uniformly.

After the cooling step is performed, performed is a laminating step which produces a laminated wafer by stacking and laminating the second wafer 4 on the surface of the first wafer 2 when condensation occurs on the surface of the cooled first wafer 2.

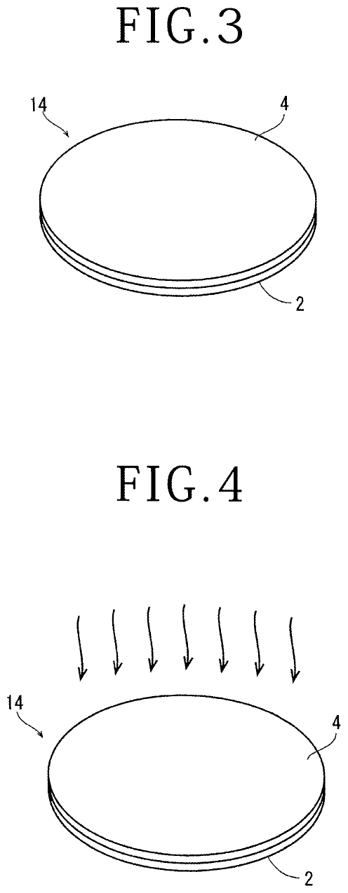

In the present embodiment, as described above, the cooling table 6 cools the first wafer 2 under an atmosphere where condensation forms on the upper surface of the first wafer 2 in the cooling step. Hence, as illustrated in FIG. 2, after condensation forms on the upper surface of the first wafer 2 mounted on the cooling table 6, and a water layer 12 is thereby formed, the second wafer 4 can be stacked and laminated on the first wafer 2 while the first wafer 2 remains placed on the cooling table 6. A laminated wafer 14 as illustrated in FIG. 3 can thereby be produced.

Incidentally, in a case where the first wafer 2 is cooled in the freezer, the first wafer 2 is exposed to such an atmosphere that condensation forms on the cooled first wafer 2. Specifically, the first wafer 2 is placed under an atmosphere of relatively high humidity at a higher temperature than in the freezer (for example, at a humidity of approximately 40% to 60% at room temperature). Then, after condensation forms on the surface of the first wafer 2 and the water layer 12 is thereby formed, the laminated wafer 14 is produced by stacking the second wafer 4 on the first wafer 2.

The water layer 12 to be formed on the surface of the first wafer 2 is preferably relatively thin and substantially uniform from the viewpoint of increasing the degree of coupling between the first wafer 2 and the second wafer 4. Conversely, when the water layer on the surface of the first wafer 2 is not uniform, for example, when the water layer includes particulate drops of water and there are thus regions in which the water layer is present and regions in which the water layer is not present on the surface of the first wafer 2, formed is a laminated wafer in which the water layer is partly absent between the first wafer 2 and the second wafer 4 when the first wafer 2 and the second wafer 4 are laminated to each other. Then, the first wafer 2 and the second wafer 4 are not firmly coupled to each other even when such a laminated wafer is subjected to heat treatment. Accordingly, jetting water to the surface of the first wafer 2 by using a sprayer or the like in order to form the water layer on the surface of the first wafer 2 is not preferable because it is difficult to form a relatively thin and substantially uniform water layer.

In this respect, the present embodiment cools the first wafer 2, and forms the water layer 12 by forming condensation on the surface of the cooled first wafer 2. Thus, the present embodiment can easily form a relatively thin and substantially uniform water layer 12. Consequently, the laminated wafer 14 in which the water layer 12 is uniformly present between the first wafer 2 and the second wafer 4 when the first wafer 2 and the second wafer 4 are laminated to each other can be formed, and the first wafer 2 and the second wafer 4 can be firmly coupled to each other by subjecting such a laminated wafer 14 to heat treatment.

In addition, because the present embodiment laminates the first wafer 2 and the second wafer 4 to each other by using the water layer 12 resulting from condensation occurring on the surface of the cooled first wafer 2, the present embodiment obviates a need for such a chemical as an acid and pure water, and can produce the laminated wafer 14 easily.

Then, after the laminating step as described above is performed, a heat treatment step of subjecting the laminated wafer 14 to heat treatment is performed (see FIG. 4), so that the first wafer 2 and the second wafer 4 are firmly coupled to each other. In the heat treatment step, it is preferable to put the laminated wafer 14 in a high temperature furnace, and subject the laminated wafer 14 to heat treatment over approximately five to six hours at a temperature of 1000° C. to 1100° C. The first wafer 2 and the second wafer 4 can thereby be coupled to each other relatively firmly.

As described above, the wafer laminating method according to the present embodiment includes the cooling step of cooling the first wafer 2, the laminating step of producing the laminated wafer 14 by stacking and laminating the second wafer 4 on the surface of the first wafer 2 when condensation forms on the surface of the cooled first wafer 2, and the heat treatment step of subjecting the laminated wafer 14 to heat treatment. Thus, the laminated wafer 14 in which the first wafer 2 and the second wafer 4 are firmly coupled to each other can be produced easily, and productivity can be improved.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer laminating method of laminating a first wafer and a second wafer to each other, the wafer laminating method comprising:
a cooling step of cooling the first wafer;
a laminating step of producing a laminated wafer by stacking and laminating the second wafer on a surface of the first wafer when condensation forms on the surface of the cooled first wafer; and
a heat treatment step of subjecting the laminated wafer to heat treatment.

2. The wafer laminating method according to claim 1, wherein
the first wafer and the second wafer are each a silicon wafer.

3. The wafer laminating method according to claim 1, wherein,
in the heat treatment step, the laminated wafer is subjected to the heat treatment at a temperature of 1000° C. to 1100° C.
